(19) United States
(12) Patent Application Publication
(10) Pub. No.: US 2007/0092994 A1
(43) Pub. Date: Apr. 26, 2007

(54) Method of manufacturing semiconductor device and a semiconductor device

(75) Inventor: Manabu Okada, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., TOKYO (JP)

(21) Appl. No.: 11/584,624

(22) Filed: Oct. 23, 2006

(30) Foreign Application Priority Data
Oct. 24, 2005 (JP) 2005-308264

(51) Int. Cl. H01L 21/00

(52) U.S. Cl. 438/106

(57) ABSTRACT

The present invention provides a method of manufacturing a semiconductor device which comprises an upper and a lower film each having a wire, and a plurality of pellets each mounted on each of the upper and lower films, where the upper and lower films are electrically connected to each other. The method includes a discriminating step for discriminating common films, each having the wire in a common pattern and the pellet electrically connected to the wire, between a conforming item and a defective item in accordance with each of a plurality of discrimination conditions, and a cutting step for selectively cutting the wires on the common films determined to be conforming items in accordance with each of the discrimination conditions, along different cutting lines to form the upper and lower films which differ in the wiring pattern.

This application is based upon and claims the benefit of priority from Japanese Patent Application No. 2005-308264 filed on Oct. 24, 2005, the content of which is incorporated by reference.

### BACKGROUND OF THE INVENTION

1. Field of the Invention

The present invention relates to a method of manufacturing a semiconductor device which comprises a plurality of wiring substrates arranged in stacks, each of which has a semiconductor element mounted on it, and to a semiconductor device.

2. Description of the Related Art

As disclosed, for example, in JP-A-2002-076266, JP-A-02-086139 (p. 3), and JP-A-64-081348 (p. 3), semiconductor devices employ a stack-type semiconductor package called “sFBGA” (stacked Fine-pitch Ball Grid Array) which comprises semiconductor elements mounted on a plurality of films, serving as wiring substrates, that are stacked one on another, and electrically connected to each other.

Another example of conventional semiconductor packages has two layers in a stack which include an upper film and a lower film, each of which is mounted with a pellet, i.e., a semiconductor element. Then, upper/lower film interconnections provided along wires of the upper and lower films are bonded with solder balls for assembly into a semiconductor package. A method of manufacturing such a conventional semiconductor package involves a mounting step, where pellets are electrically connected and mounted on the films, a discriminating step, where films mounted with pellets are discriminated between a conforming item and a defective film, and a stacking step, where films, each of which have been discriminated as a conforming item, are stacked one above another and bonded to each other.

The lower film is additionally formed with contact pins which are solder balls placed on the bottom surface thereof. These contact pins include some contact pins which are unique to the upper and lower films, in order to select either the upper pellets or the lower pellets, and a common contact pin which is used commonly by the upper and lower films.

A method of routing and connecting wires on an upper and a lower film connected to a common contact pin in a conventional semiconductor package will be described in detail with reference to FIG. 1.

As illustrated in FIG. 1, at common contact pin 109′ commonly used by upper and lower films 103, 104, wire 111 on lower film 104 is coupled to discrimination pad 106′, a bonding pad on a lower pellet, upper/lower film interconnection 107, and contact pin 109′ on the bottom surface, respectively. The bonding pad on the lower pellet is coupled to one end of wire 111″ for electric connection thereto. Also, wire 111 on upper film 103 is coupled to discrimination pad 106, a bonding pad (not shown) on an upper pellet; and upper/lower film interconnection 107, respectively. The bonding pad on the upper pellet is coupled to one end of wire 111′ for electric connection thereto.

Then, after discriminating upper film 103 to which the upper pellet has been connected, and lower film 104 to which the lower pellet has been connected, those determined to be conforming items are cut along cutting lines 110, 110′, respectively, in a cutting step for, cutting off discrimination pads, 106, 106′. Then, upper film 103 and lower film 104, from which discrimination pads 106, 106′ have been detached, are interconnected at upper/lower film interconnections 107 through solder ball 108, and securely bonded to each other. The upper and lower pellets can receive and deliver electric signals using common contact pin 109′.

Next, a method of routing and connecting wires on an upper and a lower film connected to upper/lower pellet identification contact pins in another conventional semiconductor package will be described with reference to FIG. 2.

As illustrated in FIG. 2, wires 216, 216′ are electrically connected to upper/lower pellet identification contact pins 212, 212′, respectively. Wire 216 coupled to upper pellet identification contact pin 212 is separated from wire 210′ coupled to lower pellet identification contact pin 212′, where wires 216, 216′ are independent of each other. Here, wire 216 is connected only to upper/lower film interconnection 207 and upper pellet identification contact pin 212. Wire 216′ in turn is connected to discrimination pad 206′, a bonding pad (not shown) on a lower pellet, lower pellet identification contact pin 212′, respectively. The bonding pad on the lower pellet is coupled to one end of wire 216″ for electric connection thereto.

On the other hand, wire 215 on upper film 203 is connected to discrimination pad 206, a bonding pad on an upper pellet, and upper/lower film interconnection 207, respectively. The bonding pad on the upper pellet is coupled to an end of wire 215′ for electric connection thereto.

Then, after discriminating upper film 203 to which the upper pellet has been connected, and lower film 204 to which the lower pellet has been connected, those determined to be conforming items are cut along cutting lines 210, 210′ for detaching discrimination pads 206, 206′, respectively. The upper and lower pellets can receive and deliver signals using upper/lower pellet identification contact pins 212, 212′ which are arranged independently of each other.

In the specifications of this conventional semiconductor package, upper and lower films 203, 204 have wiring patterns thereon which are unique to respective films 203, 204. Accordingly, upper and lower films 203, 204 must be specially designed independently of each other, and, at the time a pellet is connected to either the upper or lower films 203, 204, this pellet is definitely determined to be an upper pellet or a lower pellet.

The conventional method of manufacturing the semiconductor package has the following problems. As described above, the lower film is formed with contact pins in the form of solder balls on the bottom surface thereof, where several contact pins are unique to the upper and lower films in order to select either the upper or lower pellets. For this reason, the upper and lower films have their respective unique wiring patterns in order to route wires to the unique contact pins on the upper and lower films. The first problem that this causes is a high manufacturing cost for the upper and lower films each of which are specially manufactured.

Also, the upper and lower films differ from each other in the wiring length from the film connection pad of the pellet to the external contact pin and in the wiring layout. Accordingly, in the discriminating step, where the upper and lower films mounted with pellets are discriminated as a conforming item or as a defective item, the upper and lower pellets exhibit different desired characteristics which are required to discriminate each film. Therefore, in a scenario where the discrimination is made using pellets having common specifications, when determination conditions are set in favor of one film which is required to exhibit relatively strict characteristics the other film will be unnecessarily reduced in yield rate from its essential yield rate.

For example, when a pellet is found to exhibit inferior characteristics in the discriminating step, a situation can emerge, where this pellet does not meet predetermined characteristics required for an upper pellet but does meet the characteristics required for a lower pellet. In this event, this difference in characteristics is revealed when each pellet is discriminated, which is conventionally after a decision has been already made for assignment to an upper or a lower pellet. Thus, a pellet assigned for use as an upper pellet is determined to be defective, causing a reduction in yield rate upon discrimination. Consequently, a second problem lies in that when different characteristics are required for the upper and lower films, respectively, the yield rate is also reduced upon discrimination in accordance with the difference in characteristics. Also, a third problem associated with this is that when a difference occurs in characteristics between the upper and lower films, the number of assembled semiconductor packages is limited to the number of conforming films which present a lower yield rate. These three problems are all attributable to the fact that the upper and lower films are designed according to different film specifications.

The discriminating step in the conventional method of manufacturing a semiconductor device will be described with reference to FIG. 3 by way of a detailed specific example.

As illustrated in FIG. 3, pellets are first mounted on an upper and a lower film at steps 301, 302, respectively. Assume herein that the upper pellet is more difficult than the lower pellet in providing desired characteristics because of the difference in wiring length when the upper and lower films are stacked. In this event, when the upper film, on which the pellet has been mounted, is discriminated at step 303, it is contemplated that a discrimination condition imposed on the upper film is set more strict than a discrimination condition imposed on the lower film at step 304 in consideration of the yield rate after the upper and lower films are stacked.

When the discrimination conditions are set in the foregoing manner, the yield rate (number X) of the upper films at step 304 is lower than the yield rate (number Y) of the lower films at step 307, where the population of each of the upper and lower films is designated by Z, so that the number of assembled semiconductor packages is reduced in conformity to the number of conforming upper films at step 309.

In this event, (Y-X) surplus films remain unassembled, and the number of defective items of both upper and lower films, amounts to (2Z-Y-Y). Of course, the lower film may be more difficult in some cases than the upper film in ensuring desired characteristics after it has been stacked with the upper film. Presumably, by way of example, this situation can arise from the fact that the lower film is more susceptible to generate heat because the lower film is placed lower than the upper film. In this event, the number of assembled semiconductor packages is determined by the number of conforming lower films. Further, even if the upper and lower films are assumed to be discriminated in accordance with common specifications, a discrimination condition may be set in favor of one film which is required to exhibit more strict characteristics that are more difficult to realize, disadvantageously causing an unnecessary reduction in yield rate of the other film.

### SUMMARY OF THE INVENTION

It is an object of the present invention to provide a method of manufacturing a semiconductor device, which is capable of improving a final yield rate for semiconductor device, and to provide semiconductor device.

To achieve the above object, the present invention provides a method of manufacturing a semiconductor device which comprises a plurality of wiring substrates each having a wire, and a plurality of semiconductor elements mounted on each of the wiring substrates, where the wiring substrates are electrically connected to one another. The method includes a discriminating step for discriminating a common wiring substrate having the wire in a common pattern and the semiconductor element electrically connected to the wire between a conforming item and a defective item in accordance with each of a plurality of discrimination conditions, and a cutting step for selectively cutting the wires on the common wiring substrates determined as conforming items in accordance with each of the discrimination conditions, along different cutting lines to form a plurality of types of wiring substrates which have different wiring pattern.

In the method of manufacturing a semiconductor device according to the present invention configured as described above, the common wiring substrate is formed with a common wiring pattern such that it can be diverted to any of a plurality of types of wiring substrates. The common wiring substrates can be diverted from those for use as any wiring substrate to those for use as another wiring substrate in accordance with the difference in yield rate among the respective types of wiring substrates, thereby limiting the difference in yield rate among the respective types of wiring substrates to improve a final yield rate for semiconductor devices.

Additionally, the method of manufacturing a semiconductor device according to the present invention may further include, after the cutting step, a stacking step for stacking and electrically connecting the plurality of types of wiring substrates.

Alternatively, the method of manufacturing a semiconductor device according to the present invention malt include, between the discriminating step and the cutting step, the stacking step for stacking and electrically connecting the plurality of types of wiring substrates.

Further, in the method of manufacturing a semiconductor device according to the present invention, the common wiring substrate may have a branch of the wire, wherein the cutting step may include selectively cutting the common wiring substrate along the cutting line positioned in front of or behind the branch of the wire.

A semiconductor device according to the present invention includes a plurality of wiring substrates each having a wire, and a plurality of semiconductor elements each mounted on each of the wiring substrates, wherein the respective wiring substrates are electrically connected to one another. The semiconductor device includes a plurality of types of the wiring substrates having different wire patterns by selectively cutting the wires on common wiring substrates, each having a common wire pattern, along different cutting lines.

The above and other objects, features and advantages of the present invention will become apparent from the following description with reference to the accompanying drawings which illustrate examples of the present invention,

### BRIEF DESCRIPTION OF THE DRAWINGS

FIG. 1 is a perspective view illustrating a conventional semiconductor package;

FIG. 2 is a perspective view illustrating another conventional semiconductor package;

FIG. 3 is a firm chart for describing a conventional method of manufacturing a semiconductor package;

FIG. 4A is a diagram illustrating a semiconductor package according to one embodiment of the present invention;

FIG. 4B is a diagram illustrating a semiconductor package according to one embodiment of the present invention;

FIG. 5 is a bottom view illustrating the semiconductor package;

FIG. 6A is a perspective view for describing how common films are selectively cut along cutting lines and stacked one on another;

FIG. 6B is a perspective view for describing how common films are selectively cut along cutting lines and stacked one on another;

FIG. 7 is a flow chart for describing a discriminating step in a method of manufacturing the semiconductor package; and

FIG. 8 is a flow char, for describing the discriminating step in the method of manufacturing the semiconductor package.

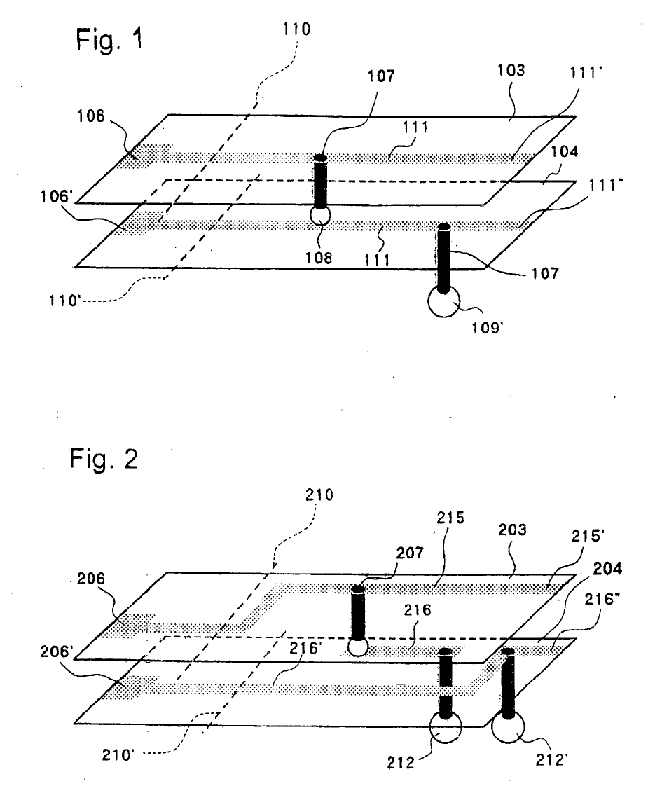

### DETAILED DESCRIPTION OF THE PREFERRED EMBODIMENT

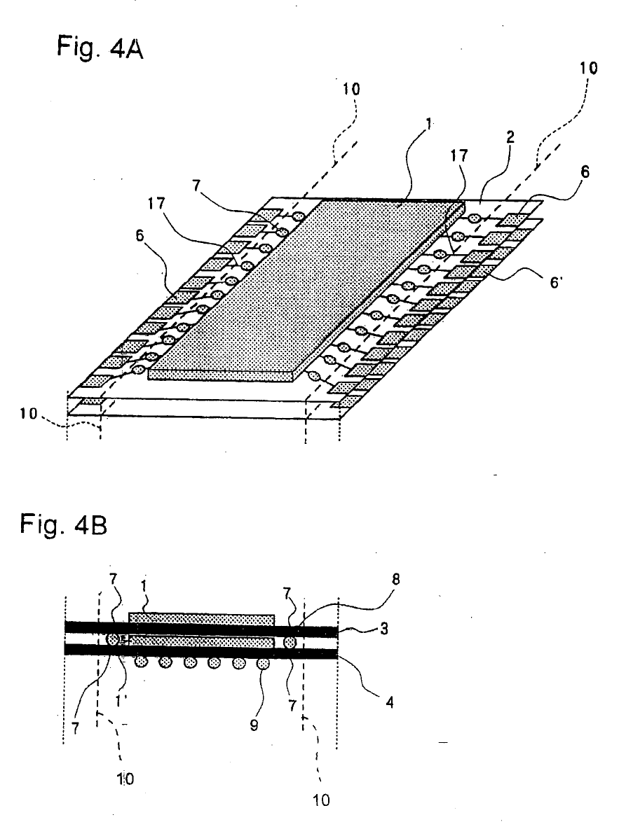

FIGS. 4A, 4B is a diagram illustrating the general configuration of a semiconductor package according to one embodiment. As illustrated in FIGS. 4A, 4B, the semiconductor package comprises pellets 1, 1′ which represent semiconductor elements; and upper film 3 and lower film 4 which serve as wiring substrates on which these pellets 1, 1′ are mounted, respectively. Stacked upper film 3 and lower film 4 are selectively formed from common films 2.

Each of upper and lower films 3, 4 comprises wires 17, and discrimination pads 6, 6′ and upper/lower film interconnections 7 electrically connected to wires 17. Pellets 1, 1′ are coupled to upper and lower films 3, 4 respectively, through wires 17. Upper and lower films 3, 4 are electrically connected to each other through their respective upper/lower film interconnections bonded through solder balls 8. Lower film 4 is also provided with contact pins 9 in the form of solder balls on the bottom surface thereof. Generally, common films 2 respectively mounted with pellets 1, 1′ are subjected to an operation test through discrimination pads (discrimination terminals) 6 on a one-by-one basis to determine whether or not it exhibits desired characteristics before they are cut into upper and lower films 3, 4 which are then stacked.

After the discrimination through the operation test, common films 2 that are determined to be conforming items are selectively cut along cutting lines 10, respectively, in a cutting step for cutting discrimination pads 6, 6′, for use as upper film 3 and lower film 4. Then, upper and lower films 3, 4 are stacked and secured by upper/lower film interconnections 7 bonded through solder balls 8. Alternatively, the cutting step for cutting discrimination pads 6, 6′ may be performed after upper and lower films 3, 4 have been stacked, i.e., after upper and lower films 3, 4 are coupled by upper/lower film interconnections 7 bonded through solder balls 8.

Wires 17 routed on lower film 4 are connected to discrimination pads 6, bonding pads (not shown) on pellet 1′, upper/lower film interconnections 7, and some of contact pins 9 on the bottom surface of lower film 4, for use in a connection of pellet 1 with discrimination pads 6′, for use in a connection of pellet 1′ with contact pins 9, and for use in a connection of upper film 3 with the contact pins. Wires 17 on upper film 3 in turn are connected to discrimination pads 6, bonding pads (not shown) on pellet 1, and upper/lower film interconnections 7, for use in a connection of upper pellet 1 with discrimination pads 6, and for use in a connection of upper pellet 1 with contact pins 9 through wires 17 routed on lower film 4.

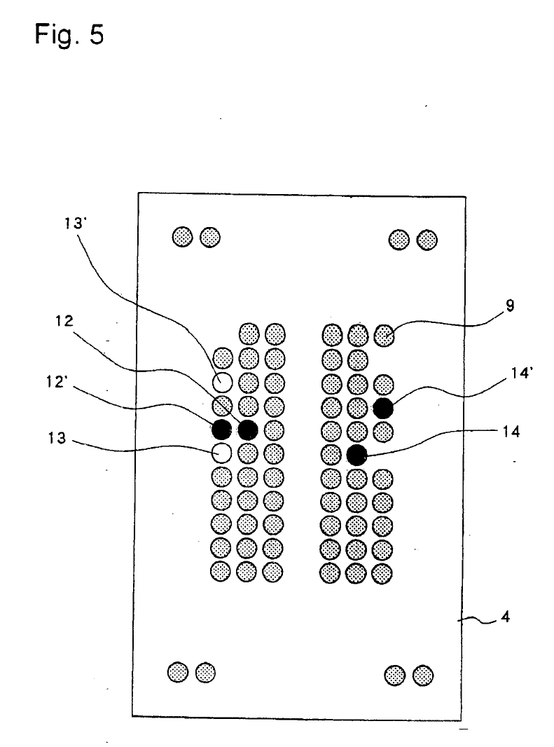

Referring now to FIG. 5, a detailed description will be given of how contact pins 9 disposed on the bottom surface of lower film 4 are connected to upper and lower films 3, 4. Upper and lower films 3, 4 have contact pins which are all common to upper and lower films 3, 4 except for features for electrically connecting some of the contact pins with wires, so that upper and lower films 3, 4 are alternately used in general. Whether common film 2 is provided to act as upper or lower film 3, 4 is determined by upper/lower pellet identification contact pins 12, 12′, 13, 13′, 14, 14′ which are partially included in upper and lower films 3, 4, respectively, independently of each other. Here, upper pellet identification contact pins 12, 13, 14 are connected to pellet 1 on upper film 3, while lower pellet identification contact pins 12′, 13′, 14′ are connected to pellet 1′ on lower film 4. Upper or lower film 3, 4 is selected by selecting the upper or lower pellet identification contact pins.

A method of manufacturing the semiconductor package configured as described above involves a discriminating step for discriminating common films 2 which have the common pattern of wires 17 electrically connected to pellets 1, 1′ under two discrimination conditions to discriminate them between a conforming item and a defective item in regard to each of these discrimination conditions, and a cutting step for selectively cutting wires 17 of common films 2, which have been determined as conforming items it) regard to each discrimination condition, along different cutting lines 10, 10′ to form two types of upper and lower films 3, 4 which differ from the pattern of wires 17. In this embodiment, wires electrically connected to a common contact pin are the same as those in the conventional semiconductor package.

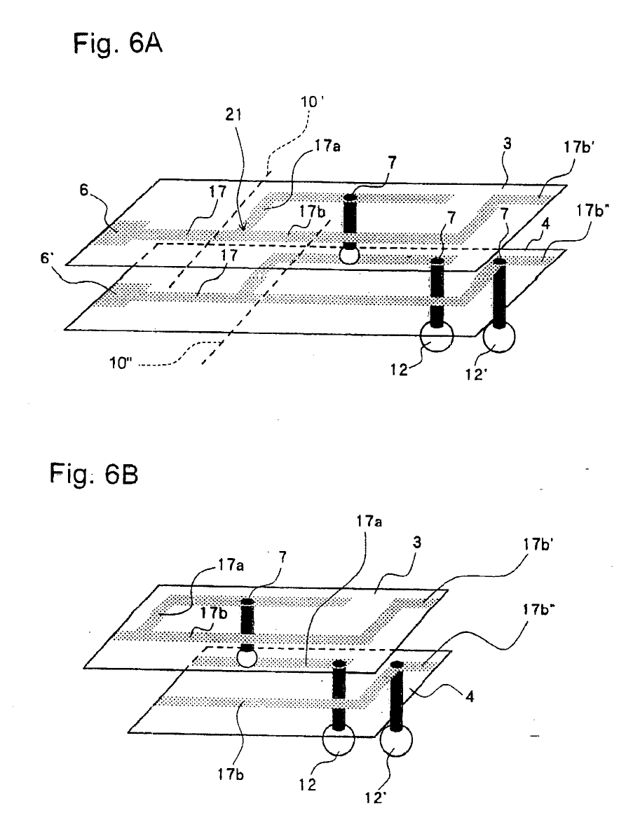

As illustrated in FIG. 6A, in the semiconductor package of this embodiment, common films 2 are not distinguished into upper and lower films 3, 4 before the cutting step for detaching discrimination pads 6, 6′, so that wire 17 is routed in the same pattern on all common films 2. Here, wire 17 on common film 2 is coupled to bonding pads on pellets 1, 1′, discrimination pads 6, 6′, upper/lower film interconnections 7, and upper/lower pellet identification contact pins 12, 12′, respectively, and wire 17 has branch 21 from which it branches into wires 17a, 17b.

Upper/lower film interconnection 7 and upper pellet identification contact pin 12 are formed on one wire 17a branched from this branch 21. The bonding pad on each of upper and lower pellets 1, 1′ is coupled to one end of wire 17b′ or 17b″ for electric connection thereto.

Then, after discriminating common films 2 to which pellets 1, 1′ have been connected, common film 2, that is determined to be a conforming item and is used as upper film 3, is cut along cutting line 10′ in front of branch 21, as viewed from discrimination pad 6. On the other hand, common film 2 used as lower film 4 is cut along cutting line 10″ behind branch 21, as viewed from discrimination pad 6′. As illustrated in FIG. 6B, after discrimination pads 6, 6′ have been detached, upper and lower films 3, 4 are securely coupled by upper/lower film interconnections 7, where upper and lower pellets 1, 1′ have independent upper/lower pellet identification contact pins 12, 12′, respectively, and can receive and deliver signals independently of each other.

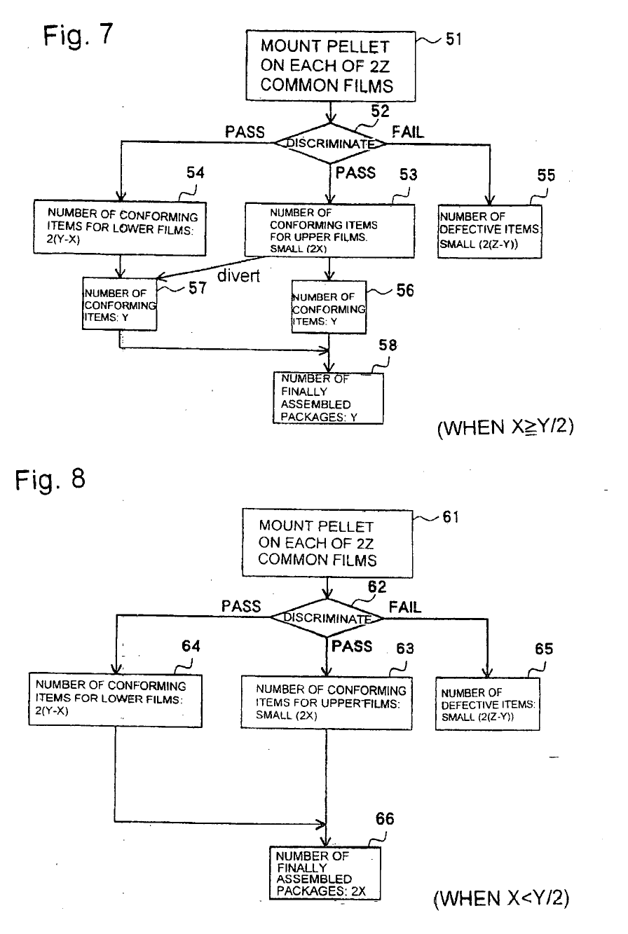

Next, referring to FIGS. 7 and 8, a description will be made on the discriminating step in the method of manufacturing the semiconductor package of this embodiment.

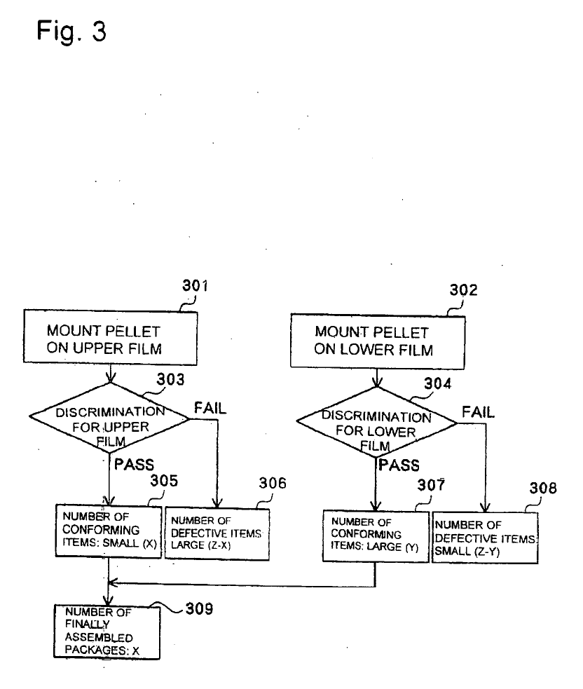

As illustrated in FIG. 7, pellets are first mounted on common films at step 51. Here, the population of the common films is chosen to be 2Z which is equal to the sum of respective populations of the aforementioned upper and lower films in FIG. 3. In accordance with the assumption made in FIG. 3, the upper film presents more difficulties in ensuring desired characteristics than the lower film when the upper and lower films are stacked. In this event, in the discrimination at step 52, two discrimination conditions are set for the upper film and lower film, respectively, such that two types of conforming items are discriminated according to the respective discrimination conditions. Here, the number of conforming items which meet the discrimination condition set for the upper film is determined to be 2X at step 53, while the number of conforming items which meet the relatively loose discrimination condition set for the lower film is determined to be 2(Y-X) at step 54. Accordingly, the number of defective items which fail to meet the respective discrimination conditions for the upper film and lower film is determined to be 2(Z-Y) at step 55.

The conforming item which meets the discrimination condition for the upper film generally satisfies desired characteristics required for the conforming item which meets the discrimination condition for the lower film. As such, (2X-Y) conforming items that are determined as eligible for use as the upper film are diverted to conforming items for use as the lower film, as long as the number of conforming items resulting from the discrimination under the respective conditions satisfy 2Y≧2≧X≧2(Y-X) and [Y≧X≧Y/2] (step 53). In this way, Y semiconductor packages are finally assembled (steps 56, 57), with no remaining conforming item but with 2(Z-Y) defective films. Thus, as compared with the conventional manufacturing method which provides X assembled semiconductor packages, the manufacturing method of this embodiment increases the number of assembled semiconductor packages to Y, with a consequent reduction in the number of remaining conforming items and the number of defective films.

In another scenario, where the number of conforming items resulting from the discrimination under the respective conditions satisfy 0≦2X≦2(Y-X) and [0≦X≦Y/2], the conforming items determined as eligible for use as the upper film cannot be diverted to conforming items for use as the lower film. However, even in this scenario, 2X semiconductor packages can be finally assembled (step 66), which is twice as much as the number of assembled semiconductor packages in the conventional manufacturing method. In this event, the number of (2Y-4X) conforming items remains unused, and the number of defective films is calculated to be 2(Z-Y) (step 65), in step with an increase in the number of assembled semiconductor packages, which is smaller than before, though a definite comparison cannot be made with the prior art.

As described above, the method of manufacturing the semiconductor package has the discriminating step for discriminating common films 2 under two different discrimination conditions between conforming items for use as upper films and lower films, respectively, and can therefore diver conforming items for use as one, for example, upper film to conforming items for use as the other, lower film in accordance with the number of conforming items for use as each of the upper film and lower film. Consequently, this manufacturing method can increase a final yield rate for the semiconductor packages to improve the productivity of the semiconductor packages.

Also, the method of manufacturing the semiconductor package eliminates the need to, specially manufacturing upper and lower films 3, 4, respectively, by forming upper and lower films 3, 4, from common films 2, and can therefore reduce the manufacturing cost of wiring substrates made of film. Further, the method of manufacturing the semiconductor package uses common film 2 to solve the complexity of handling two types of films, which differ in specifications, for the upper and lower films, thus contributing to a reduction in production time.

The method of manufacturing the semiconductor package described above is configured to have the discriminating step for discriminating common films between conforming items for use as upper films and lower films. It should be understood, however, that the present invention may also be applied to a method of manufacturing a semiconductor package which has a discriminating step for discriminating a conforming item for use as another film which is formed by cutting a common film along a different cutting line, such that the conforming item is diverted to the other film or from the other film.

While preferred embodiment of the present invention have been described using specific terms, such description is for illustrative purposes only, and it is to be understood that changes and variations may be made without departing from the spirit or scope of the following claims.

What is claimed is:

1. A method of manufacturing a semiconductor device which comprises a plurality of wiring substrates each having a wire, and a plurality of semiconductor elements each mounted on each of said wiring substrates, said wiring substrates being electrically connected to one another, said method comprising:
a discriminating step for discriminating a common wiring substrate having the wire in a common pattern and having the semiconductor element electrically connected to the wire, between a conforming item and a defective item in accordance with each of a plurality of discrimination conditions; and
a cutting step for selectively cutting the wires on the common wiring substrates determined to be conforming items in accordance with each of the discrimination conditions, along different cutting lines to form a plurality of types of wiring substrates which differ in the wiring pattern.

2. The method of manufacturing a semiconductor device according to claim 1, further comprising, after said cutting step, a stacking step for stacking and electrically connecting the plurality of types of wiring substrates.

3. The method of manufacturing a semiconductor device according to claim 1, further comprising, between said discriminating step and said cutting step, a stacking step for stacking and electrically connecting the plurality of types of wiring substrates.

4. The method of manufacturing a semiconductor device according to claim 1, wherein:
said common wiring substrate has a branch of the wire, and
said cutting step includes selectively cutting the common wiring substrate along the cutting line positioned in front of or behind the branch of the wire.

5. The method of manufacturing a semiconductor device according to claim 1, wherein said common wiring substrate comprises a discrimination terminal for discriminating the characteristics of said common wiring substrate to which the semiconductor element is electrically connected, and wherein said discrimination terminal is detached by cutting said common wiring substrate along the cutting line.

6. The method of manufacturing a semiconductor device according to claim 1, wherein said common wiring substrate comprises a plurality of identification terminals for identifying the semiconductor element, and wherein said method further comprises the step of selectively connecting one of the plurality of identification terminals electrically to the wire.

7. A semiconductor device comprising a plurality of wiring substrates each having a wire, and a plurality of semiconductor elements each mounted on each of said wiring substrates, said respective wiring substrates being electrically connected to one another,
wherein said semiconductor device comprises a plurality of types of said wiring substrates having different wire patterns by selectively cutting the wires on common wiring substrates, each having a common wire pattern, along different cutting lines.
